(19) United States
(12) Patent Application Publication
(10) Pub. No.: US 2026/0214827 A1
(43) Pub. Date: Jul. 23, 2026

(54) STACKED MEMORY APPARATUS

(71) Applicant: Dell Products L.P., Round Rock, TX (US)

(72) Inventors: Hao Wu Yang, Taipei City (TW); Qinghong He, Austin, TX (US); Shih-Wei Yang, Taoyuan City (TW); Jing-Tang Wu, New Taipei City (TW)

(21) Appl. No.: 19/032,909

(22) Filed: Jan. 21, 2025

(51) Int. Cl. H05K 7/14; H05K 7/02

(52) U.S. Cl. CPC H05K 7/1489; H05K 7/023

(57) ABSTRACT

A stacked memory apparatus, including a first memory module including first openings; a second memory module including second openings; a bracket including: first tabs, with each tab of the first tabs including a first aperture; and second tabs, with each tab of the second tabs including a second aperture; first fasteners, wherein each first fastener is positioned through the first aperture of a respective first tab of the bracket and through a respective first opening of the first memory module to engage with a threaded hole of respective standoffs of a chassis to couple the first memory module and the bracket to the chassis; and second fasteners, wherein each second fastener is positioned through a respective second opening of the second memory module to engage with the second aperture of a respective second tab to couple the second memory module to the bracket.

### BACKGROUND

### Field of the Disclosure

The disclosure relates generally to an information handling system, and in particular, a stacked memory apparatus for the information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes, thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Balancing space inside a casing of an information handling system for physical memory storage involves several compromises. Adding more memory modules can limit the space available for other components, such as additional storage drives or larger cooling systems.

### SUMMARY

Innovative aspects of the subject matter described in this specification may be embodied in a stacked memory apparatus, including: a first memory module including a plurality of first openings; a second memory module including a plurality of second openings; a bracket including: a first plurality of tabs, with each tab of the first plurality of tabs including a first aperture; and a second plurality of tabs, with each tab of the second plurality of tabs including a second aperture; a first set of fasteners, wherein each fastener of the first set of fasteners is positioned through the first aperture of a respective tab of the first plurality of tabs of the bracket and through a respective first opening of the plurality of first openings of the first memory module to engage with a threaded hole of respective standoffs of a chassis to couple the first memory module and the bracket to the chassis; and a second set of fasteners, wherein each fastener of the second set of fasteners is positioned through a respective second opening of the plurality of second openings of the second memory module to engage with the second aperture of a respective tab of the second plurality of tabs to couple the second memory module to the bracket.

Other embodiments of these aspects include corresponding systems and apparatus.

These and other embodiments may each optionally include one or more of the following features. For instance, the plurality of first openings are positioned along one or more sides of the first memory module; and the plurality of second openings are positioned along one or more sides of the second memory module. The bracket includes: a base; a first extension; and a second extension, wherein the base is positioned between the first extension and the second extension at a first side of the bracket. At least a portion of the first extension extends orthogonal to the base; and at least a portion of the second extension extends orthogonal to the base. One or more of the first plurality of tabs extend from the first extension; and one or more of the first plurality of tabs extend from the second extension. One or more of the second plurality of tabs extend from the first extension; and one or more of the second plurality of tabs extend from the second extension. The base includes a base hole, the base hole including one or more of the first plurality of tabs. One or more of the second plurality of tabs extend from the base. The second aperture of each of the second plurality of tabs is threaded. The base includes one or more third apertures, the stacked memory apparatus further including: one or more third fasteners, wherein each fastener of the third set of fasteners is positioned through a respective third aperture of the one or more third apertures of the base to engage with threaded holes of respective standoffs of the chassis to further couple the bracket to the chassis. A copper foil layer coupled to the bracket, wherein the copper foil layer is positioned between the first memory module and the second memory module.

The details of one or more embodiments of the subject matter described in this specification are set forth in the accompanying drawings and the description below. Other potential features, aspects, and advantages of the subject matter will become apparent from the description, the drawings, and the claims.

### BRIEF DESCRIPTION OF DRAWINGS

FIG. 1 is a block diagram of selected elements of an embodiment of an information handling system.

FIG. 2 illustrates a block diagram of the information handling system.

FIG. 3A illustrates a perspective view of a stacked memory apparatus assembled.

FIG. 3B illustrates a perspective view of an exploded view of the stacked memory apparatus.

FIG. 3C illustrates a top-down view of the stacked memory apparatus partially assembled.

FIG. 4A illustrates a perspective view of a first memory module coupled to a chassis of the information handling system.

FIG. 4B illustrates a perspective view of a bracket being coupled to the chassis of the information handling system.

FIG. 4C illustrates a perspective view of a second memory module being coupled to the bracket.

FIG. 5 illustrates a perspective view of the stacked memory apparatus including additional connection points of the bracket.

FIG. 6 illustrates the bracket of the stacked memory apparatus including a copper foil layer.

### DESCRIPTION OF PARTICULAR EMBODIMENT(S)

This disclosure discusses a stacked memory apparatus of an information handling system. Specifically, this disclosure discusses a staked memory apparatus including a first memory module including a plurality of first openings; a second memory module including a plurality of second openings; a bracket including: a first plurality of tabs, with each tab of the first plurality of tabs including a first aperture; and a second plurality of tabs, with each tab of the second plurality of tabs including a second aperture; a first set of fasteners, wherein each fastener of the first set of fasteners is positioned through the first aperture of a respective tab of the first plurality of tabs of the bracket and through a respective first opening of the plurality of first openings of the first memory module to engage with a threaded hole of respective standoffs of a chassis to couple the first memory module and the bracket to the chassis; and a second set of fasteners, wherein each fastener of the second set of fasteners is positioned through a respective second opening of the plurality of second openings of the second memory module to engage with the second aperture of a respective tab of the second plurality of tabs to couple the second memory module to the bracket.

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, an information handling system may include an instrumentality or aggregate of instrumentalities operable to compute, classify, process, transmit, receive, retrieve, originate, switch, store, display, manifest, detect, record, reproduce, handle, or utilize various forms of information, intelligence, or data for business, scientific, control, entertainment, or other purposes. For example, an information handling system may be a personal computer, a PDA, a consumer electronic device, a network storage device, or another suitable device and may vary in size, shape, performance, functionality, and price. The information handling system may include memory, one or more processing resources such as a central processing unit (CPU) or hardware or software control logic. Additional components of the information handling system may include one or more storage devices, one or more communications ports for communicating with external devices as well as various input and output (I/O) devices, such as a keyboard, a mouse, and a video display. The information handling system may also include one or more buses operable to transmit communication between the various hardware components.

For the purposes of this disclosure, computer-readable media may include an instrumentality or aggregation of instrumentalities that may retain data and/or instructions for a period of time. Computer-readable media may include, without limitation, storage media such as a direct access storage device (e.g., a hard disk drive or floppy disk), a sequential access storage device (e.g., a tape disk drive), compact disk, CD-ROM, DVD, random access memory (RAM), read-only memory (ROM), electrically erasable programmable read-only memory (EEPROM), and/or flash memory (SSD); as well as communications media such as wires, optical fibers, microwaves, radio waves, and other electromagnetic and/or optical carriers; and/or any combination of the foregoing.

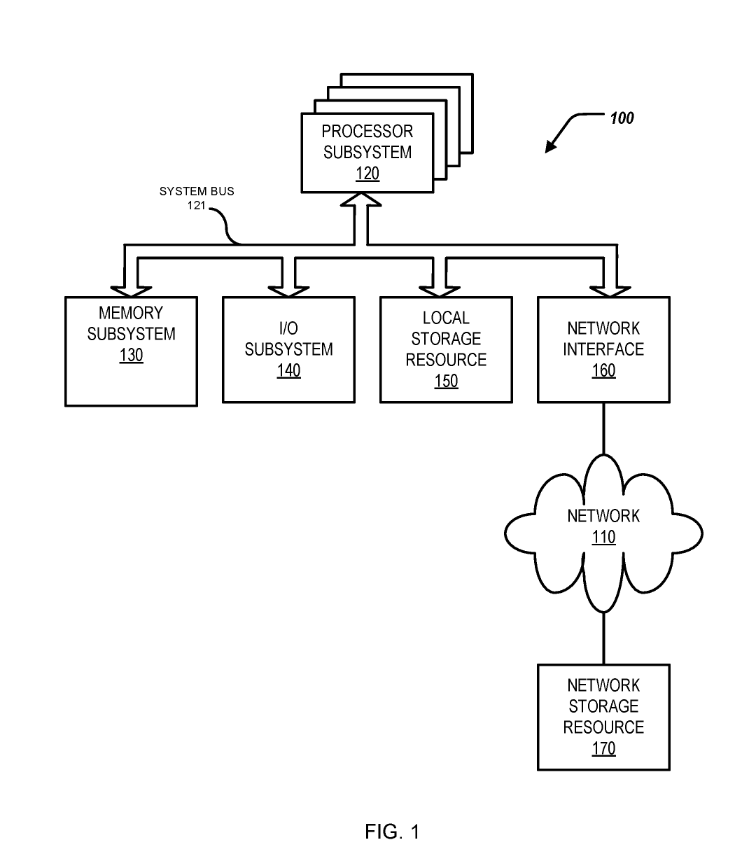

Particular embodiments are best understood by reference to FIGS. 1-6 wherein like numbers are used to indicate like and corresponding parts.

Turning now to the drawings, FIG. 1 illustrates a block diagram depicting selected elements of an information handling system 100 in accordance with some embodiments of the present disclosure. In various embodiments, information handling system 100 may represent different types of portable information handling systems, such as, display devices, head mounted displays, head mount display systems, smart phones, tablet computers, notebook computers, media players, digital cameras, 2-in-1 tablet-laptop combination computers, and wireless organizers, or other types of portable information handling systems. In one or more embodiments, information handling system 100 may also represent other types of information handling systems, including desktop computers, server systems, controllers, and microcontroller units, among other types of information handling systems. Components of information handling system 100 may include, but are not limited to, a processor subsystem 120, which may comprise one or more processors, and system bus 121 that communicatively couples various system components to processor subsystem 120 including, for example, a memory subsystem 130, an I/O subsystem 140, a local storage resource 150, and a network interface 160. System bus 121 may represent a variety of suitable types of bus structures, e.g., a memory bus, a peripheral bus, or a local bus using various bus architectures in selected embodiments. For example, such architectures may include, but are not limited to, Micro Channel Architecture (MCA) bus, Industry Standard Architecture (ISA) bus, Enhanced ISA (EISA) bus, Peripheral Component Interconnect (PCI) bus, PCI-Express bus, HyperTransport (HT) bus, and Video Electronics Standards Association (VESA) local bus.

As depicted in FIG. 1, processor subsystem 120 may comprise a system, device, or apparatus operable to interpret and/or execute program instructions and/or process data, and may include one or more processing resources such as a central processing unit (CPU), microprocessor, microcontroller, digital signal processor (DSP), application specific integrated circuit (ASIC), or another digital or analog circuitry configured to interpret and/or execute program instructions and/or process data. In some embodiments, processor subsystem 120 may interpret and/or execute program instructions and/or process data stored locally (e.g., in memory subsystem 130 and/or another component of information handling system 100). In the same or alternative embodiments, processor subsystem 120 may interpret and/or execute program instructions and/or process data stored remotely (e.g., in network storage resource 170).

Also in FIG. 1, memory subsystem 130 may comprise a system, device, or apparatus operable to retain and/or retrieve program instructions and/or data for a period of time (e.g., computer-readable media). Memory subsystem 130 may comprise random access memory (RAM), electrically erasable programmable read-only memory (EEPROM), a PCMCIA card, flash memory, magnetic storage, opto-magnetic storage, and/or a suitable selection and/or array of volatile or non-volatile memory that retains data after power to its associated information handling system, such as system 100, is powered down.

In information handling system 100, I/O subsystem 140 may comprise a system, device, or apparatus generally operable to receive and/or transmit data to/from/within information handling system 100. I/O subsystem 140 may represent, for example, a variety of communication interfaces, graphics interfaces, video interfaces, user input interfaces, and/or peripheral interfaces. In various embodiments, I/O subsystem 140 may be used to support various peripheral devices, such as a touch panel, a display adapter, a keyboard, an accelerometer, a touch pad, a gyroscope, an IR sensor, a microphone, a sensor, a camera, or another type of peripheral device.

Local storage resource 150 may comprise computer-readable media (e.g., hard disk drive, floppy disk drive, CD-ROM, and/or other types of rotating storage media, flash memory, EEPROM, and/or another type of solid state storage media) and may be generally operable to store instructions and/or data. Likewise, the network storage resource may comprise computer-readable media (e.g., hard disk drive, floppy disk drive, CD-ROM, and/or other types of rotating storage media, flash memory, EEPROM, and/or other types of solid state storage media) and may be generally operable to store instructions and/or data.

In FIG. 1, network interface 160 may be a suitable system, apparatus, or device operable to serve as an interface between information handling system 100 and a network 110. Network interface 160 may enable information handling system 100 to communicate over network 110 using a suitable transmission protocol and/or standard, including, but not limited to, transmission protocols and/or standards enumerated below with respect to the discussion of network 110. In some embodiments, network interface 160 may be communicatively coupled via network 110 to a network storage resource 170. Network 110 may be a public network or a private (e.g., corporate) network. The network may be implemented as, or may be a part of, a storage area network (SAN), a personal area network (PAN), a local area network (LAN), a metropolitan area network (MAN), a wide area network (WAN), a wireless local area network (WLAN), a virtual private network (VPN), an intranet, the Internet or another appropriate architecture or system that facilitates the communication of signals, data and/or messages (generally referred to as data). Network interface 160 may enable wired and/or wireless communications (e.g., NFC or Bluetooth) to and/or from information handling system 100.

In particular embodiments, network 110 may include one or more routers for routing data between client information handling systems 100 and server information handling systems 100. A device (e.g., a client information handling system 100 or a server information handling system 100) on network 110 may be addressed by a corresponding network address including, for example, an Internet protocol (IP) address, an Internet name, a Windows Internet name service (WINS) name, a domain name or other system name. In particular embodiments, network 110 may include one or more logical groupings of network devices such as, for example, one or more sites (e.g., customer sites) or subnets. As an example, a corporate network may include potentially thousands of offices or branches, each with its own subnet (or multiple subnets) having many devices. One or more client information handling systems 100 may communicate with one or more server information handling systems 100 via any suitable connection including, for example, a modem connection, a LAN connection including the Ethernet, or a broadband WAN connection including DSL, Cable, Ti, T3, Fiber Optics, Wi-Fi, or a mobile network connection including GSM, GPRS, 3G, or WiMax.

Network 110 may transmit data using a desired storage and/or communication protocol, including, but not limited to, Fibre Channel, Frame Relay, Asynchronous Transfer Mode (ATM), Internet protocol (IP), other packet-based protocol, small computer system interface (SCSI), Internet SCSI (iSCSI), Serial Attached SCSI (SAS) or another transport that operates with the SCSI protocol, advanced technology attachment (ATA), serial ATA (SATA), advanced technology attachment packet interface (ATAPI), serial storage architecture (SSA), integrated drive electronics (IDE), and/or any combination thereof. Network 110 and its various components may be implemented using hardware, software, or any combination thereof.

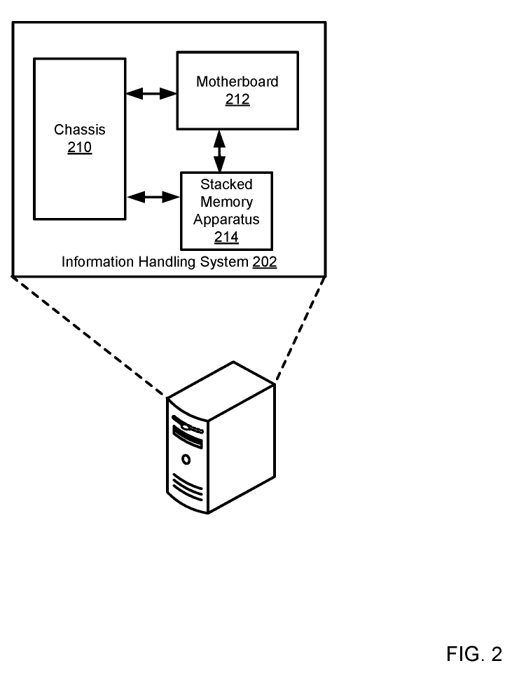

FIG. 2 illustrates a block diagram of the information handling system 202. The information handling system 202 can include a chassis 210, a motherboard 212, and a stacked memory apparatus 214. The motherboard 212 can be coupled to the chassis 210. The stacked memory apparatus 214 can be coupled to the motherboard 212 and the chassis 210. In some examples, the information handling system 202 is similar to, or includes, the information handling system 100 of FIG. 1.

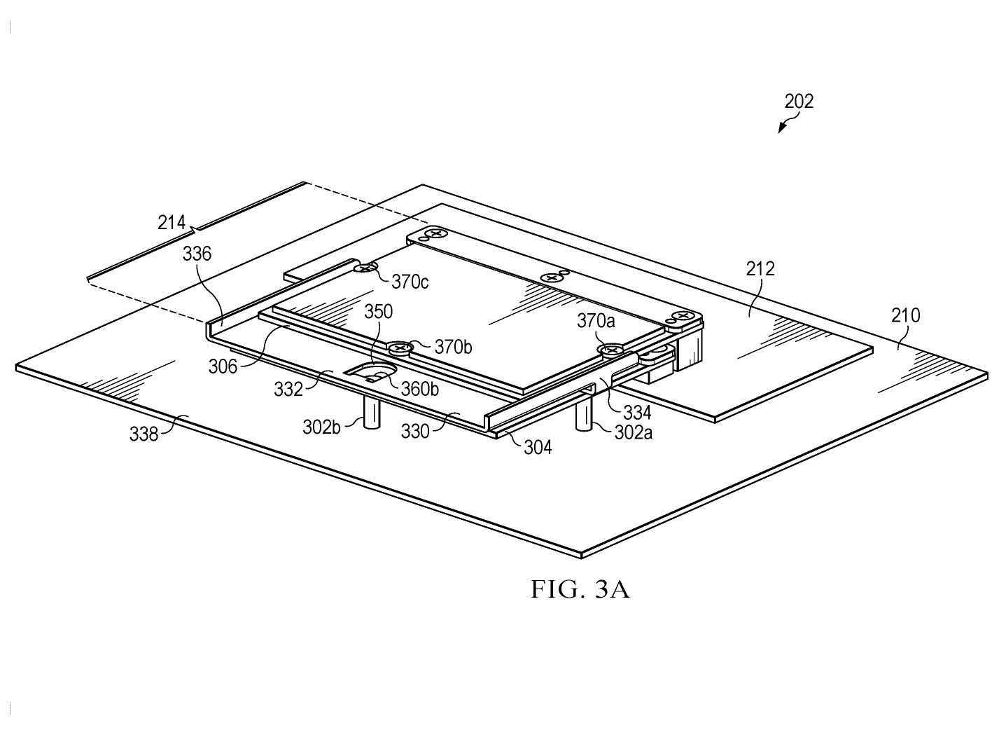

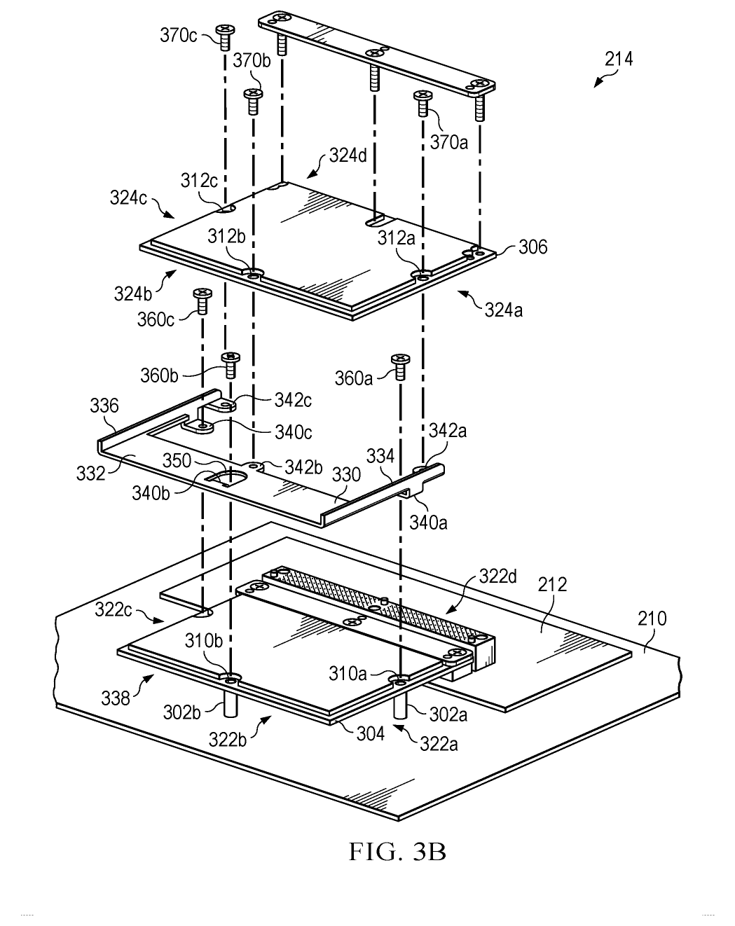

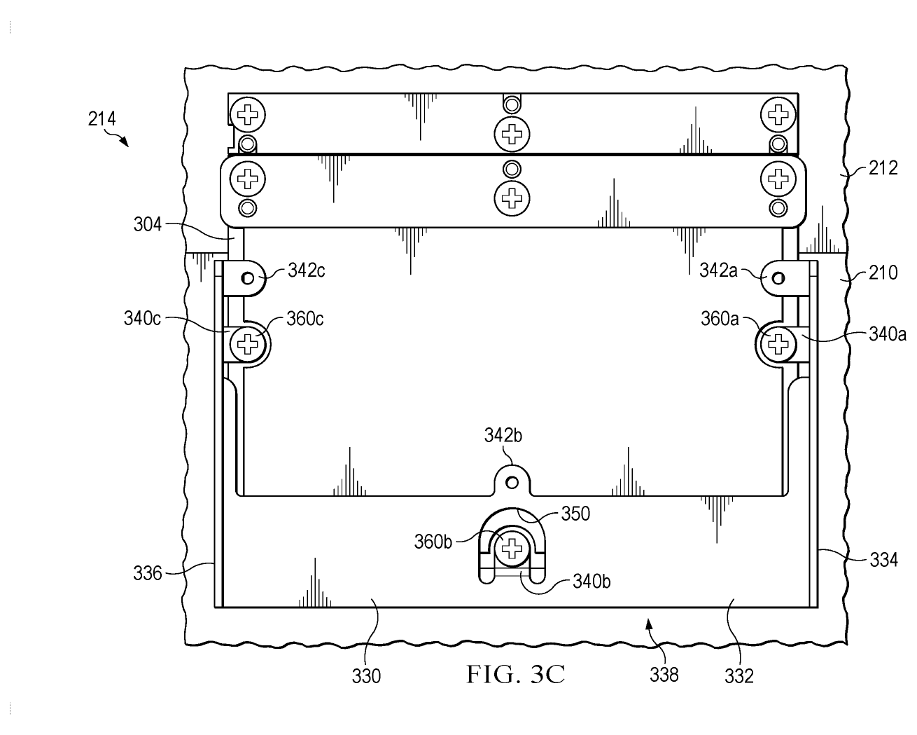

FIG. 3A illustrates a perspective view of the stacked memory apparatus 214 assembled; FIG. 3B illustrates a perspective view of an exploded view of the stacked memory apparatus 214; and FIG. 3C illustrates a top-down view of the stacked memory apparatus 214 partially assembled. Referring to FIGS. 3A-3C, the information handling system 202 includes the chassis 210. The chassis 210 can include standoffs 302a, 302b, 302c (collectively referred to as standoffs 302) (for simplicity of illustration, standoff 302c is not illustrated). Each of the standoffs 302 can include a threaded hole.

The information handling system 202 can include the motherboard 212 coupled to the chassis 210.

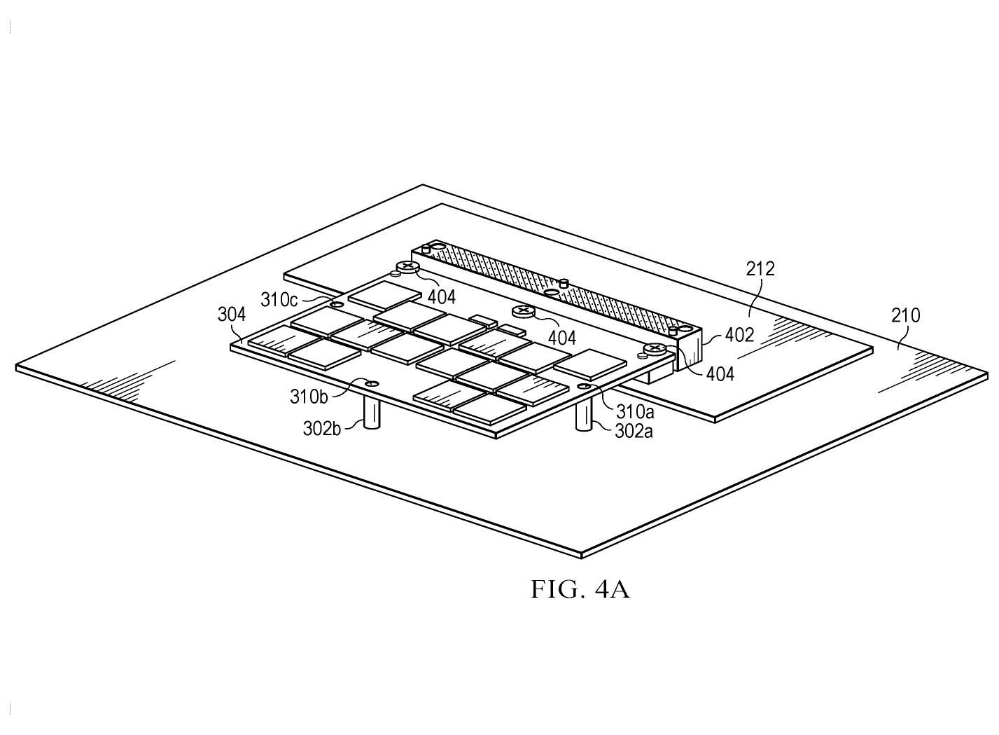

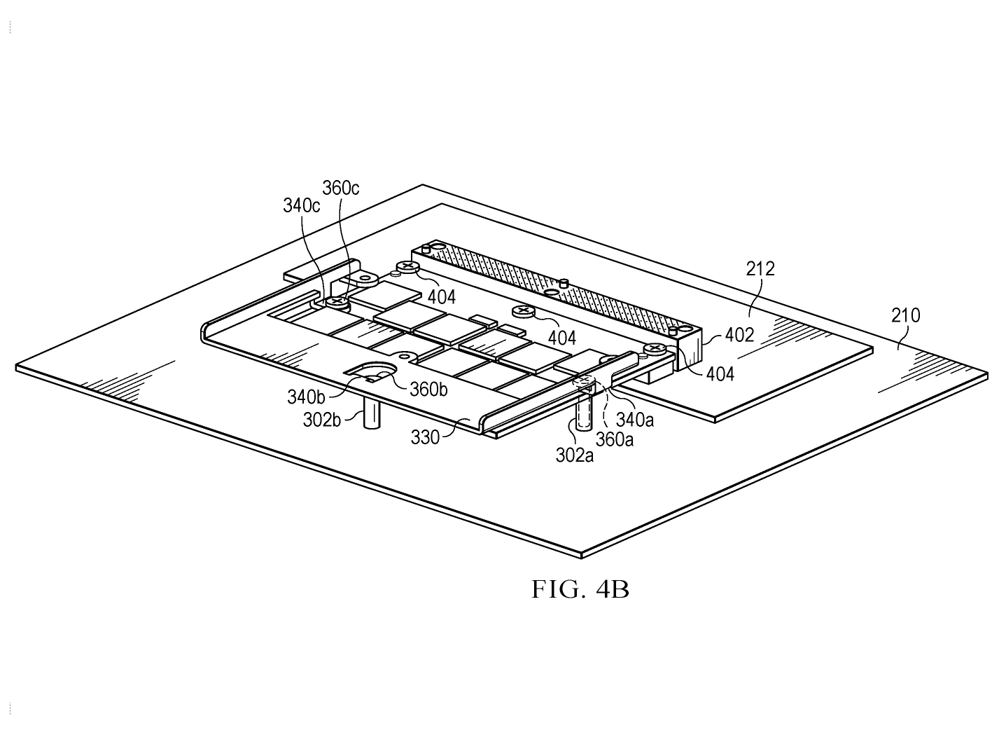

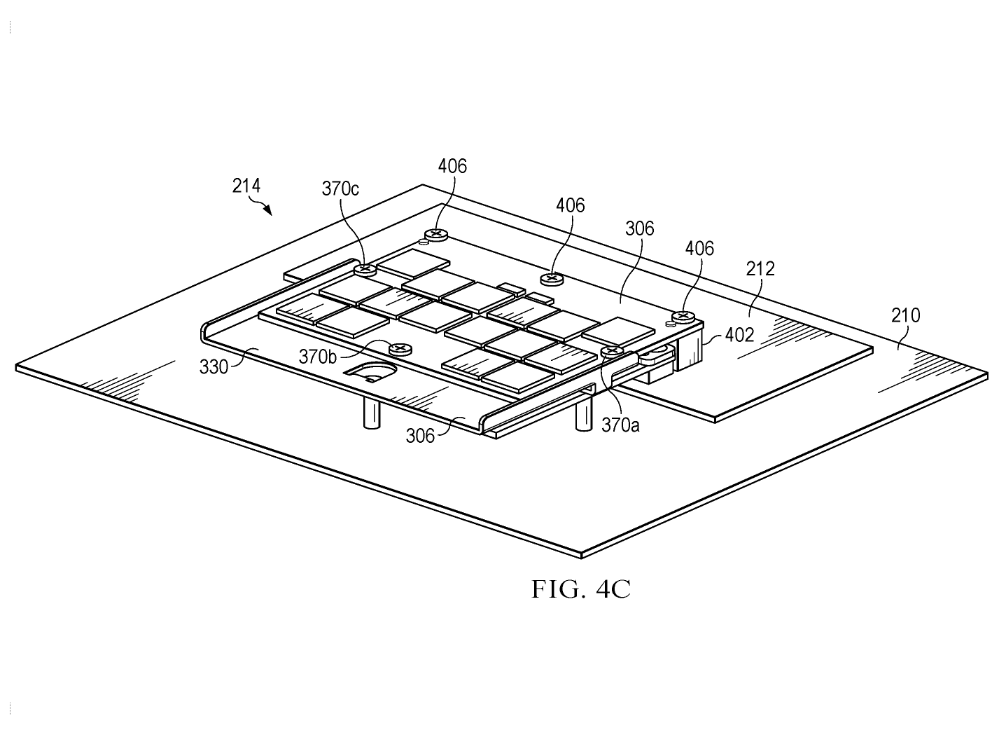

The information handling system 202 can include the stacked memory apparatus 214. The stacked memory apparatus 214 can include a first memory module 304 and a second memory module 306. The first memory module 304 can include first openings 310a, 310b, 310c (collectively referred to as first openings 310) (first opening 310c shown in FIG. 4A). The first memory module 304 can include sides 322a, 322b, 322c, 322d (collectively referred to as sides 322). The first opening 310a can be positioned along the side 322a; the first opening 310b can be positioned along the side 322b; and the first opening 310c can be positioned along the side 322c.

The second memory module 306 can include second openings 312a, 312b, 312c (collectively referred to as second openings 312). The second memory module 306 can include sides 324a, 324b, 324c, 324d (collectively referred to as sides 324). The second opening 312a can be positioned along the side 324a; the second opening 312b can be positioned along the side 324b; and the second opening 312c can be positioned along the side 324c.

The stacked memory apparatus 214 can include a bracket 330. The bracket 330 can include a base 332, a first extension 334, and a second extension 336. The base 332 is positioned between the first extension 334 and the second extension 336 at a first side 338 of the bracket 330. The bracket 330 can be considered to have a general “U”-based shape. The first extension 334 can extend orthogonal to the base 332; and the second extension 336 can extend orthogonal to the base 332.

The first extension 334 can include a first tab 340a; the base 332 can include a first tab 340b; and the second extension 336 can include a first tab 340c (first tabs 340a, 340b, 340c collectively referred to as first tabs 340). Each of the first tabs 340 can include a first aperture (or hole). The first aperture of the first tabs 340 can be threaded. The first extension 334 can include a second tab 342a; the base 332 can include a second tab 342b; and the second extension 336 can include a second tab 342c (second tabs 342a, 342b, 342c collectively referred to as second tabs 342). Each of the second tabs 342 can include a second aperture (or hole). The second aperture of the second tabs 342 can be threaded.

The base 332 can include a base hole 350. The base hole 350 can include the first tab 340b. That is, the first tab 340b is positioned within the base hole 350 of the base 332.

The stacked memory apparatus 214 can include first fasteners 360a, 360b, 360c (collectively referred to as first fasteners 360). Each first fastener 360 is positioned through a first aperture of a respective first tab 340 and through a respective first opening 310 of the first memory module 304 to engage with the threaded hole of respective standoffs 302 of the chassis 210. Specifically, the first fastener 360a is positioned through the first aperture of the first tab 340a and through the first opening 310a of the first memory module 304 to engage with the threaded hole of the standoff 302a of the chassis 210; the first fastener 360b is positioned through the first aperture of the first tab 340b and through the first opening 310b of the first memory module 304 to engage with the threaded hole of the standoff 302b of the chassis 210; and the first fastener 360c is positioned through the first aperture of the first tab 340c and through the first opening 310c of the first memory module 304 to engage with the threaded hole of the standoff 302c of the chassis 210.

Furthermore, each first fastener 360 is positioned through a first aperture of a respective first tab 340 and through a respective first opening 310 of the first memory module 304 to engage with the threaded hole of respective standoffs 302 of the chassis 210 to couple the first memory module 304 and the bracket 330 to the chassis 210 such that the first memory module 304 is connected to the motherboard 212. Specifically, the first fastener 360a is positioned through the first aperture of the first tab 340a and through the first opening 310a of the first memory module 304 to engage with the threaded hole of the standoff 302a of the chassis 210 to couple the first memory module 304 and the bracket 330 to the chassis 210 such that the first memory module 304 is connected to the motherboard 212; the first fastener 360b is positioned through the first aperture of the first tab 340b and through the first opening 310b of the first memory module 304 to engage with the threaded hole of the standoff 302b of the chassis 210 to couple the first memory module 304 and the bracket 330 to the chassis 210 such that the first memory module 304 is connected to the motherboard 212; and the first fastener 360c is positioned through the first aperture of the first tab 340c and through the first opening 310c of the first memory module 304 to engage with the threaded hole of the standoff 302c of the chassis 210 to couple the first memory module 304 and the bracket 330 to the chassis 210 such that the first memory module 304 is connected to the motherboard 212.

The stacked memory apparatus 214 can include second fasteners 370a, 370b, 370c (collectively referred to as second fasteners 370). Each second fastener 370 is positioned through a respective second opening 312 of the second memory module 306 to engage with the second aperture of respective second tabs 342. Specifically, the second fastener 370a is positioned through the second opening 312a of the second memory module 306 to engage with the second aperture of the second tab 342a; the second fastener 370b is positioned through the second opening 312b of the second memory module 306 to engage with the second aperture of the second tab 342b; and the second fastener 370c is positioned through the second opening 312c of the second memory module 306 to engage with the second aperture of the second tab 342c.

Furthermore, each second fastener 370 is positioned through a respective second opening 312 of the second memory module 306 to engage with the second aperture of respective second tabs 342 to couple the second memory module 306 to the bracket 330 such that the second memory module 306 is connected to the motherboard 212. Specifically, the second fastener 370a is positioned through the second opening 312a of the second memory module 306 to engage with the second aperture of the second tab 342a to couple the second memory module 306 to the bracket 330 such that the second memory module 306 is connected to the motherboard 212; the second fastener 370b is positioned through the second opening 312b of the second memory module 306 to engage with the second aperture of the second tab 342b to couple the second memory module 306 to the bracket 330 such that the second memory module 306 is connected to the motherboard 212; and the second fastener 370c is positioned through the second opening 312c of the second memory module 306 to engage with the second aperture of the second tab 342c to couple the second memory module 306 to the bracket 330 such that the second memory module 306 is connected to the motherboard 212.

FIG. 4A illustrates a perspective view of the first memory module 304 coupled to the chassis 210 of the information handling system 202. FIG. 4B illustrates a perspective view of the bracket 330 being coupled to the chassis 210 of the information handling system 202. FIG. 4C illustrates a perspective view of the second memory module 306 being coupled to the bracket 330. Referring to FIG. 4A, the first memory module 304 is coupled to the chassis 210. Specifically, the first memory module 304 is aligned with the chassis 210 such that the first openings 310 of the first memory module 304 are aligned with respective standoffs 302 of the chassis 210. Further, the first memory module 304 can be coupled to a connector 402 of the motherboard 212 via fasteners 404.

Referring to FIG. 4B, the bracket 330 can be aligned with the first memory module 304 and the chassis 210 such that the first tabs 340 of the bracket 330 are aligned with respective first openings 310 of the first memory module 304 and aligned with the respective standoffs 302 of the chassis 210. The first fasteners 360 couple the bracket 330 and the first memory module 304 to the chassis 210 through respective first apertures of the first tabs 340 of the bracket 330, through respective first openings 310 of the first memory module 304, and to respective standoffs 302 of the chassis 210.

Referring to FIG. 4C, the second memory module 306 is coupled to the bracket 330. Specifically, the second memory module 306 is aligned with the bracket 330 such that the second openings 312 of the second memory module 306 are aligned with respective second tabs 342 of the bracket 330. The second fasteners 370 couple the second memory module 306 to the chassis 210 through respective second openings 312 of the second memory module 306 and through respective second apertures of the second tabs 342 of the bracket 330. Further, the second memory module 306 can be coupled to the connector 402 of the motherboard 212 via fasteners 406.

To that end, the second memory module 306 is able to be directly mounted/coupled to the motherboard 212 (via the bracket 330) for structural support of the second memory module 306. Additionally, the first memory module 304 and the second memory module 306 are mounted to the motherboard 212 without increasing a footprint of the stacked memory apparatus 214. That is, by the stacked memory apparatus 214 including the second memory module 306 (in addition to the first memory module 304), the footprint (or real estate) of the stacked memory apparatus 214 with respect to the motherboard 212 is the same (not increased). Thus, a denser memory allocation is available at the motherboard 212 without sacrificing additional space on the motherboard 212.

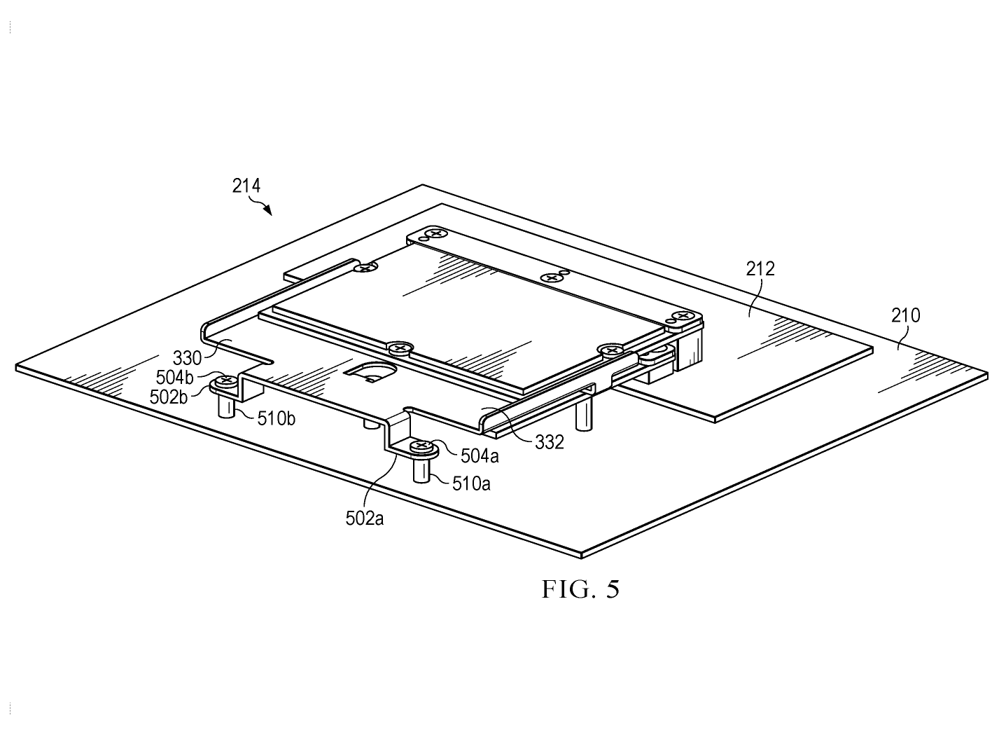

FIG. 5 illustrates a perspective view of the stacked memory apparatus 214 including additional connection points of the bracket 330. Specifically, the base 332 includes third tabs 502a, 502b (collectively referred to as tabs 502). Each of the third tabs 502 can include a third aperture (or hole). The third aperture of the third tabs 502 can be threaded. The stacked memory apparatus 214 further includes third fasteners 504a, 504b (collectively referred to as third fasteners 504). Each of the third fasteners 504 is positioned through a respective third aperture of the third tabs 502 of the base 332 to engage with threaded holes of the respective standoffs 510a, 510b (collectively referred to as standoffs 510) of the chassis 210 to further couple the bracket 330 to the chassis 210. Specifically, the third fastener 504a is positioned through the third aperture of the third tab 502a of the base 332 to engage with the third hole of the standoff 510a of the chassis 210 to further couple the bracket 330 to the chassis 210; and the third fastener 504b is positioned through the third aperture of the third tab 502b of the base 332 to engage with the third hole of the standoff 510b of the chassis 210 to further couple the bracket 330 to the chassis 210.

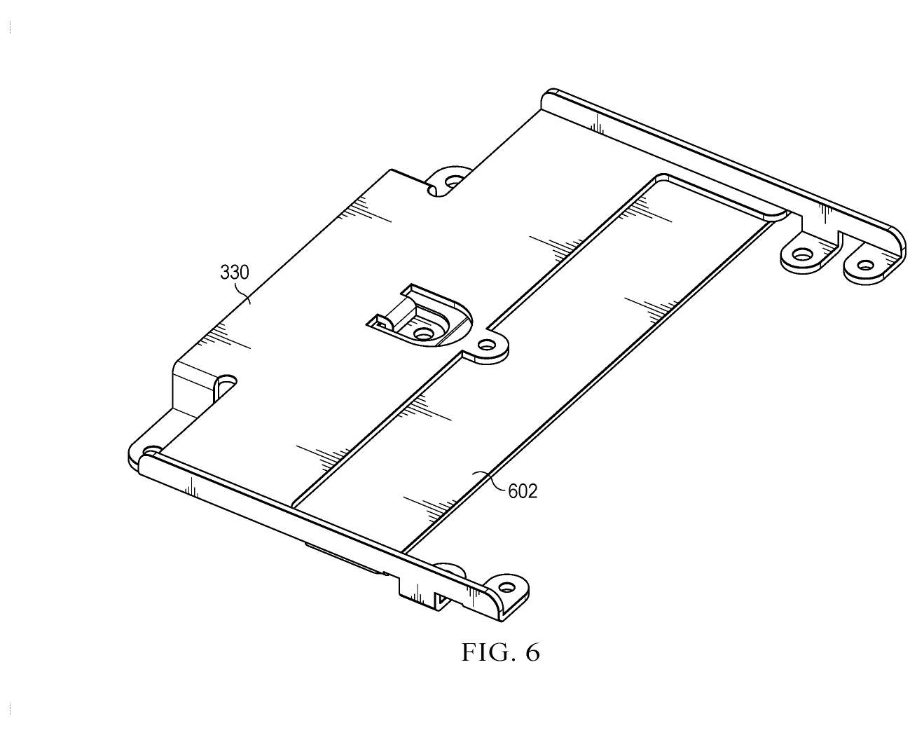

FIG. 6 illustrates the bracket 330 of the stacked memory apparatus 214 including a copper foil layer. Specifically, a copper foil layer 602 can be coupled to the bracket 330. The copper foil layer 602 can be positioned between the first memory module 204 and the second memory module 206. The copper foil layer 602 can facilitate extracting thermal energy (heat) from the first memory module 204 and/or the second memory module 206.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

What is claimed is:

1. A stacked memory apparatus, including:
a first memory module including a plurality of first openings;
a second memory module including a plurality of second openings;
a bracket including:
a first plurality of tabs, with each tab of the first plurality of tabs including a first aperture; and
a second plurality of tabs, with each tab of the second plurality of tabs including a second aperture;
a first set of fasteners, wherein each fastener of the first set of fasteners is positioned through the first aperture of a respective tab of the first plurality of tabs of the bracket and through a respective first opening of the plurality of first openings of the first memory module to engage with a threaded hole of respective standoffs of a chassis to couple the first memory module and the bracket to the chassis; and
a second set of fasteners, wherein each fastener of the second set of fasteners is positioned through a respective second opening of the plurality of second openings of the second memory module to engage with the second aperture of a respective tab of the second plurality of tabs to couple the second memory module to the bracket.

2. The stacked memory apparatus of claim 1, wherein
the plurality of first openings are positioned along one or more sides of the first memory module; and
the plurality of second openings are positioned along one or more sides of the second memory module.

3. The stacked memory apparatus of claim 1, wherein the bracket includes:
a base;
a first extension; and
a second extension,
wherein the base is positioned between the first extension and the second extension at a first side of the bracket.

4. The stacked memory apparatus of claim 3, wherein
at least a portion of the first extension extends orthogonal to the base; and
at least a portion of the second extension extends orthogonal to the base.

5. The stacked memory apparatus of claim 3, wherein:
one or more of the first plurality of tabs extend from the first extension; and
one or more of the first plurality of tabs extend from the second extension.

6. The stacked memory apparatus of claim 5, wherein:
one or more of the second plurality of tabs extend from the first extension; and
one or more of the second plurality of tabs extend from the second extension.

7. The stacked memory apparatus of claim 6, wherein the base includes a base hole, the base hole including one or more of the first plurality of tabs.

8. The stacked memory apparatus of claim 7, wherein one or more of the second plurality of tabs extend from the base.

9. The stacked memory apparatus of claim 1, wherein the second aperture of each of the second plurality of tabs is threaded.

10. The stacked memory apparatus of claim 3, wherein the base includes one or more third apertures, the stacked memory apparatus further including:
one or more third fasteners, wherein each fastener of the third set of fasteners is positioned through a respective third aperture of the one or more third apertures of the base to engage with threaded holes of respective standoffs of the chassis to further couple the bracket to the chassis.

11. The stacked memory apparatus of claim 1, further including:
a copper foil layer coupled to the bracket,
wherein the copper foil layer is positioned between the first memory module and the second memory module.

12. A stacked memory apparatus, including:
a first memory module including a first opening;
a second memory module including a second opening;
a bracket including:
a first tab including a first aperture; and
a second tab including a second aperture;
a first fastener positioned through the first aperture of the first tab of the bracket and through the first opening of the first memory module to engage with a threaded hole of a standoff of a chassis to couple the first memory module and the bracket to the chassis; and
a second fastener positioned through the second opening of the second memory module to engage with the second aperture of the second tab to couple the second memory module to the bracket.

13. An information handling system, comprising:
a chassis, including one or more standoffs, each standoff include a threaded hole;
a motherboard coupled to the chassis;
a stacked memory apparatus, including:
a first memory module including a plurality of first openings;
a second memory module including a plurality of second openings;
a bracket including:
a first plurality of tabs, with each tab of the first plurality of tabs including a first aperture; and
a second plurality of tabs, with each tab of the second plurality of tabs including a second aperture;
a first set of fasteners, wherein each fastener of the first set of fasteners is positioned through the first aperture of a respective tab of the first plurality of tabs of the bracket and through a respective first opening of the plurality of first openings of the first memory module to engage with a threaded hole of respective standoffs of a chassis to couple the first memory module and the bracket to the chassis such that the first memory module is connected to the motherboard; and
a second set of fasteners, wherein each fastener of the second set of fasteners is positioned through a respective second opening of the plurality of second openings of the second memory module to engage with the second aperture of a respective tab of the second plurality of tabs to couple the second memory module to the bracket such that the second memory module is connected to the motherboard.

14. The information handling system of claim 13, wherein the bracket includes:
a base;
a first extension; and
a second extension,
wherein the base is positioned between the first extension and the second extension at a first side of the bracket.

15. The information handling system of claim 14, wherein:
at least a portion of the first extension extends orthogonal to the base; and
at least a portion of the second extension extends orthogonal to the base.

16. The information handling system of claim 15, wherein:
one or more of the first plurality of tabs extend from the first extension; and
one or more of the first plurality of tabs extend from the second extension.

17. The information handling system of claim 16, wherein:
one or more of the second plurality of tabs extend from the first extension; and
one or more of the second plurality of tabs extend from the second extension.

18. The information handling system of claim 14, wherein the base includes a base hole, the base hole including one or more of the first plurality of tabs.

19. The information handling system of claim 18, wherein one or more of the second plurality of tabs extend from the base.

20. The information handling system of claim 13, wherein the second aperture of each of the second plurality of tabs is threaded.
